(19) United States
(12) Patent Application Publication
(10) Pub. No.: US 2008/0272843 A1
(43) Pub. Date: Nov. 6, 2008

(54) Integrated Amplifier Circuit

(76) Inventors: Martin Krauss, Obersulm (DE); Marco Schwarzmueller, Heilbronn (DE)

Correspondence Address: Muncy, Geissler, Olds & Lowe, PLLC, P.O. BOX 1364, FAIRFAX, VA, 22038-1364, US

(21) Appl. No.: 12/115,521

(22) Filed: May 5, 2008

Related U.S. Application Data
(60) Provisional application No. 60/924,285, filed on May 8, 2007.

(30) Foreign Application Priority Data
May 4, 2007 (DE) DE10 2007021402.4

(51) Int. Cl. H03F 3/45

(52) U.S. Cl. 330/253

(57) ABSTRACT

An integrated amplifier circuit is provided with an amplifier that is composed of at least two amplifier regions, the amplifier regions being arranged about a symmetry point, wherein each amplifier region has a plurality of transistors in a transistor region, and wherein transistors from different amplifier areas are arranged within the same transistor region. According to an aspect, provision is made that each amplifier region has at least two transistors. Whereby the integrated amplifier circuit can be used for semiconductor components

This nonprovisional application claims priority to German Patent Application No. 102007021402.4, which was filed in Germany on May 4, 2007, and to U.S. Provisional Application No. 60/924,285, which was filed on May 8, 2007, and which are both herein incorporated by reference.

### BACKGROUND OF THE INVENTION

1. Field of the Invention

The present invention concerns an integrated amplifier circuit with at least two amplifiers, each of which is composed of at least two amplifier regions that are arranged to be radially symmetric to one another.

2. Description of the Background Art

A prior art integrated amplifier circuit has two amplifiers, each of which is subdivided into two amplifier regions, wherein each of the two amplifiers has two transistors that are electrically coupled to one another and that are arranged such that they are spatially separated from one another.

The prior art amplifier circuit is realized as a semiconductor component. To this end, a geometrically structured layer configuration of multiple layers with different electrical properties and different geometries is implemented on a base substrate, for example on a semiconductor crystal, thus forming the electrical components of the amplifier.

During manufacture of the base substrate, and during the subsequent application and structuring of the layers, process-related inhomogeneities with regard to the electrical properties of the individual layers of the semiconductor component may arise. Such inhomogeneities can adversely affect the desired uniformity of the amplifiers. For this reason, it is known to divide the amplifiers into two amplifier regions, which are implemented with spatial separation. This spatial separation permits at least partial compensation of properties of the base substrate and of the layer configuration that typically vary linearly over the surface of the base substrate; these property variations are also known as property gradients.

A prior art arrangement of two amplifiers, each of which is subdivided into two amplifier regions, is known as a “common centroid” arrangement. In this context, the amplifier regions of both amplifiers are arranged to be radially symmetric with respect to a common symmetry point, and each occupies a square area. Such an arrangement is known from U.S. Publication No. 2005/0026322

For certain applications of an integrated amplifier circuit, in which an especially small deviation between the properties of the amplifiers is required, the prior art arrangement is not adequate with regard to compensation of inhomogeneities of the semiconductor component.

### SUMMARY OF THE INVENTION

It is therefore an object of the present invention to provide an integrated amplifier circuit in which the amplifiers have at least nearly identical electrical characteristics.

In this regard, an input of the integrated amplifier circuit is provided with an amplifier that has at least two amplifier regions, whereby the amplifier regions are arranged about a symmetrical point, and whereby each amplifier region has a plurality of transistors arranged in transistor regions, the transistors being arranged in different amplifier regions within the same transistor region. Further, each amplifier region has at least two transistors. The transistors that are associated with one another in each case can be arranged directly adjacent to or spaced apart from one another. In this way, an additional spatial distribution is achieved for each amplifier region, by which means an averaging of the property gradients takes place. In this way, homogeneous properties are achieved for the amplifier regions and thus for the amplifier. In other words, the transistors are arranged in the amplifier regions in such a way that property gradients resulting from the production process are at least largely compensated.

In an embodiment, each transistor region has a symmetrical axis, whereby transistors from different amplifier regions within a transistor region are arranged along the symmetrical axis.

In another embodiment of the invention, provision is made that amplifier regions of adjacent amplifiers are arranged to be bilaterally symmetrical to one another. Each of the amplifier regions has an outer contour, which is to say a boundary line determined by the electronic components of the amplifier region in question. According to the invention, the outer contour of a first amplifier region corresponds to the outer contour of an adjacent second amplifier region, which in turn is part of another amplifier. The outer contours of the adjacent amplifier regions can be mapped congruently onto one another by reflection at an axis of reflection. In this way, under the assumption of essentially linear property gradients on the semiconductor component, a desirable averaging of the properties of the individual amplifier regions is achieved.

In another embodiment of the invention, provision is made that transistors of adjacent amplifiers are arranged to be bilaterally symmetrical to one another. The transistors of the relevant amplifier regions have a predefinable electrical wiring that is chosen such that the same input signal is provided to multiple transistors. In this way, a functional position for the respective amplifier can be assigned for these transistors. The functional position of the transistors is selected according to the invention such that transistors with the same functional position in adjacent amplifier regions of different amplifiers are located at the same bilaterally symmetrical geometric positions. In this way, a further homogenization of the properties of the semiconductor substrate is achieved for the amplifiers. Preferably, axes of reflection for the transistors of the amplifier regions pass through a common symmetry point of the amplifier.

In another embodiment of the invention, provision is made that the transistors in the amplifier regions are arranged to be bilaterally symmetrical to one another. The transistors in an amplifier region are associated with different inputs of the amplifier, so that they can be supplied with input signals that may differ from one another. In order to achieve the most homogeneous processing of the input signals, each of the transistors that are associated with the same inputs are arranged to be bilaterally symmetrical to one another. In this regard, a bilaterally symmetrical arrangement of the transistors includes both the first case, in which transistors are mapped onto one another by the reflection operation, and the second case, in which transistors are mapped onto themselves by the reflection operation. Mapping onto themselves takes place when the axis of reflection passes through the transistor or transistors. Preferably, an axis of reflection for the transistors of an amplifier region passes through a symmetry point of the amplifier regions.

In another embodiment of the invention, provision is made that the amplifiers are wired as differential amplifiers. In a differential amplifier, a voltage difference between two voltages applied to the associated amplifiers is amplified. In the inventive amplifier circuit, the advantageous embodiment with multiple transistors in transistor groups and the symmetrical arrangement of the transistors achieves a matching of the gains of the amplifiers that is less than 0.5 percent, preferably less than 0.25 percent, and especially preferably less than 0.1 percent.

In another embodiment of the invention, provision is made that empty regions are located between the amplifier regions. Undesired electrical coupling between adjacent amplifier regions can be reduced by the empty regions. In prior art amplifiers, efforts are made to achieve the densest possible arrangement of the amplifier regions in order to achieve the most homogeneous conditions. In the inventive amplifier circuit, a spacing and thus decoupling of the amplifier regions is achieved as a result of empty regions, since the symmetrical arrangement of the transistors in the amplifier regions and the symmetrical arrangement of the amplifier regions result in a homogenization of the property gradients on the semiconductor component in any case.

In another embodiment of the invention, provision is made that the amplifier regions, in particular the transistors, are arranged with four-way radial symmetry. An advantageous arrangement is achieved in this way, especially for a differential amplifier that has two mutually coupled amplifiers that can be subdivided into amplifier regions and individual transistors. With four-way radial symmetry, each of the amplifier regions can be appropriately mapped onto each of the other amplifier regions by rotations with an angle of rotation of 90 degrees about a symmetry point.

In another embodiment of the invention, provision is made that transistors are electrically combined into transistor groups and that at least two transistor groups of an amplifier region have a common center point. In this regard, transistors that are electrically coupled to a common input terminal are defined as a transistor group. The transistors of a transistor group are preferably arranged in the amplifier regions such that they are arranged with radial symmetry with regard to the amplifier regions and are oriented with bilateral symmetry within the respective amplifier region. Since each of the transistors occupies an area, preferably equal, on the semiconductor component, a center point or an area midpoint for all transistors of a transistor group can be identified. Provision is made according to the invention that center points of at least two transistor groups, which can be associated with the same or different amplifiers, coincide at a common point, since an especially advantageous homogenization of property gradients of a semiconductor component can be achieved in this way.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic representation of an amplifier with multiple inputs,

FIG. 2 is a schematic representation of an internal structure of the amplifier from FIG. 1,

FIG. 3 is a detailed representation of an amplifier region from FIG. 2; and

FIG. 4 is a schematic representation of the arrangement of the transistors in an amplifier circuit that is constructed of two amplifiers.

### DETAILED DESCRIPTION

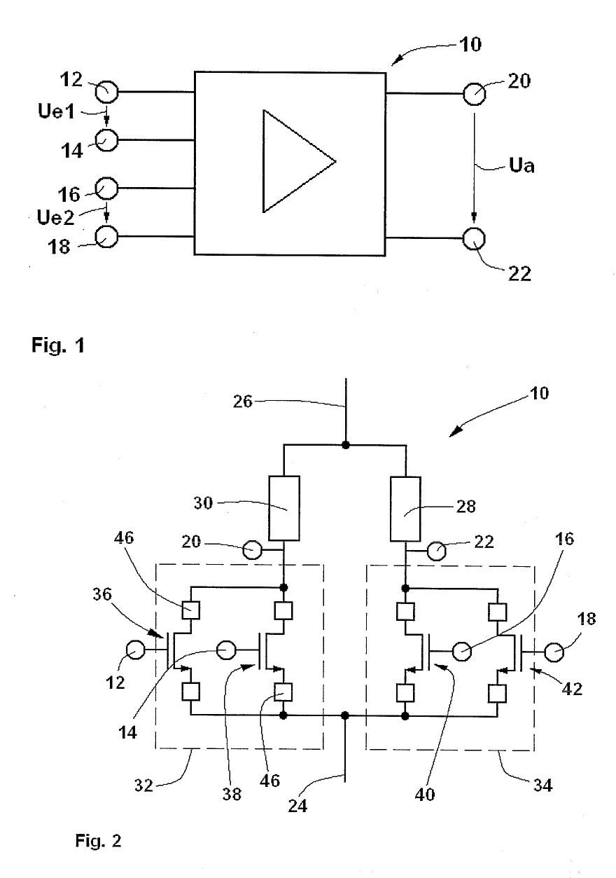

An amplifier 10 shown in FIG. 1, which is implemented on a semiconductor component that is not shown in detail, has four input terminals 12, 14, 16, 18, and two output terminals 20, 22. When the amplifier 10 is used in an electronic circuit, which is not shown in detail, input voltages Ue1 and Ue2 are applied to two respective sets of adjacent input terminals 12 and 14, and 16 and 18. The amplifier 10 is connected to a supply voltage through connections that are not shown, and outputs as an output voltage Ua a voltage that results as the product of the respective input voltage Ue1 or Ue2 and an associated gain G1 or G2 determined by the respective amplifier region. In this regard, the gain G1 or G2 is determined by the electrical properties of the respective amplifier region, not shown in detail in FIG. 1, within the amplifier 10.

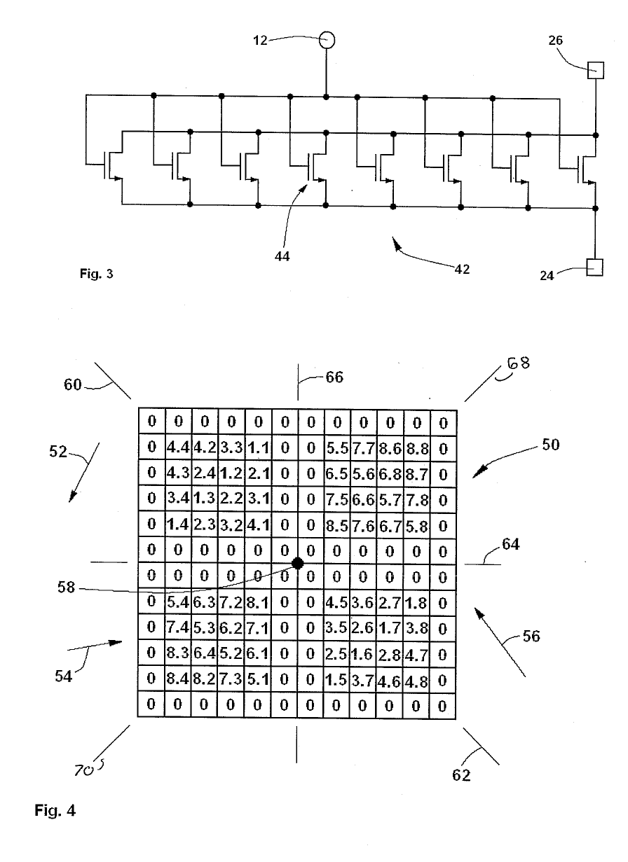

In FIG. 2, the amplifier 10 from FIG. 1 is shown in detail. The amplifier 10 is subdivided into two amplifier regions 32, 34 designed to be mirror images, each of which has two parallel-connected transistor groups 36, 38 or 40, 42 represented by a transistor circuit symbol. Each of the transistor groups 36, 38, 40, 42 is made up of eight transistors 44, as is shown in detail in FIG. 3, and is connected to the supply terminals 24, 26 through connecting node 46. In addition, each of the transistor groups 36, 38, 40, 42 is connected to one of the input terminals 12, 14, 16, 18, while the output terminals 20 and 22 are each connected to the series resistors 28, 30. Electrical potentials applied to the input terminals 12, 14, 16, 18 serve as control voltages for the associated transistor groups 36, 38, 40, 42.

When different input voltages Ue1 and Ue2 are applied to the input terminals 12, 14, 16, 18, a current, which is dependent on the respective electrical potential of the applied input voltage, is established for each of the transistors implemented as NMOS field effect transistors. This current flows through the applicable series resistor 28, 30. Accordingly, a voltage difference between the input voltages Ue1 and Ue2 is expressed as a potential difference between the two series resistors 28, 30. This potential difference can be tapped from the output terminals 20, 22 for further processing.

As is shown in detail in FIG. 3, each transistor group 36, 38, 40, 42 is structured as an arrangement of eight transistors 44, which are connected in parallel to one another. In order to permit as extensive as possible compensation of property gradients of the semiconductor component (which is not shown in detail), the transistors 44 are arranged according to a distribution shown in detail in FIG. 4. In FIG. 4, the transistors 44 are labeled with a number combination, where the first digit identifies the association with the applicable transistor group 36, 38, 40, 42, and the second digit—after the decimal point—provides the sequential number of the transistor 44 within the respective transistor group.

FIG. 4 shows an amplifier circuit 50 with two amplifiers, each of which has four transistor groups of eight transistors 44, so that the amplifier circuit 50 contains a total of sixty-four transistors 44. By way of example, we shall consider the first transistor group, which is composed of transistors 1.1 through 1.8, in order to explain the relevant symmetry conditions for the homogeneous properties of the amplifier circuit.

The transistors 44 of the first transistor group are arranged in the amplifier circuit 50 in such a way that the transistors 1.1 through 1.4 can be mapped onto the respective associated transistors 1.5 through 1.8 by means of rotation about an axis of rotation that is perpendicular to the plane of the drawing and passes through a symmetry point 58. This means, for example, that with a rotation about 180 degrees, the transistor 44 labeled 1.1 can be mapped onto the transistor 44 labeled 1.5. Moreover, the transistors 44 are oriented within the transistor groups in such a way that, in the case of reflection about the axes of reflection 60, 62, each of which passes through the symmetry point 58 in the plane of the drawing as a diagonal of the square shown, they are each reflected again onto transistors 44 belonging to the same transistor group. Some of the transistors 44 are mapped onto themselves by such a reflection operation, such as is the case for the transistor 4.1 in the event of reflection about the axis of rotation 60, for example.

The transistors 44 of the applicable transistor groups are arranged such that they fulfill multiple symmetry conditions, thus ensuring that property gradients, such as are indicated by the arrows 52, 54, and 56, can be compensated at least nearly completely. Such property gradients arise as a result of production processes for the semiconductor components, and may, for example, occur in response to inhomogeneous vapor deposition on the surface of the substrate material during manufacture of the semiconductor element. Property gradients can concern electrical conductivity, for example, which increases linearly in the direction of the arrow 52. As a result, the transistor 8.4, by way of example, has different electrical conductivity properties than the transistor 8.8. However, since both transistors belong to the same transistor group and the same input signal is applied to them, averaging of the electrical properties takes place, and thus the desired property compensation of the property gradients takes place.

Each of the transistors 44 in the transistor regions is arranged with a square outer contour and in a grid with constant separation, so each of the transistors 44 occupies the same square area on the semiconductor component. Adjacent transistor regions can be mapped onto one another by reflection. In this context, both a superposition of the outer contours of the applicable transistor regions and a suitable mapping of the transistors 44 within the transistor regions are ensured. In other words, when reflection takes place about one of the axes of reflection 64, 66, the transistor region with the transistors 1.1 through 4.4, for example, can be mapped onto the adjacent transistor region with the transistors 5.1 through 8.4 or onto the transistor region with the transistor 5.5 through 8.8.

All transistors 44 of the transistor groups in the amplifier circuit 50 have a common centroid, which coincides with the symmetry point 58. This can be understood using the first transistor group with the transistors 1.1 through 1.8 as an example. Since this symmetry condition also applies to the other transistor groups, and all centroids of the transistor groups coincide in the symmetry point 58, the result is especially balanced compensation of the property gradients across the semiconductor component.

The arrangement of the transistors 44 in the four transistor areas, even within each of the transistor areas, complies with at least one further symmetry requirement. As noted above, the first numbers 1 and 2 of the transistors 44 represents an affiliation of the transistors to the transistor groups 36 and 38. Correspondingly, these transistors are associated with the amplifier region 32. Accordingly, the numbers 3 and 4 of the transistors 44 represents an affiliation of the transistors to the transistor groups 40 and 42 of the amplifier region 34. Thus, each of the four transistor region transistors 44 is contained from each of the amplifier areas 32, 34, as for example the transistor region with the axes of reflection 60 contains the transistors 4.4 and 2.4.

Moreover, within each of the transistor regions, the transistors 44 are arranged that are along an axis that is formed as a symmetrical axis, preferably a reflection axis 60, 62, 68, 70. For example, the transistors 4.4, 4.3, 4.2, 3.3, 2.4, 3.4, 1.4, 1.3, 1.2, 1.1, 2.1, 2.2, 2.3, 3.2, 3.1, and 4.1 are arranged along the reflection axis 60. It can be seen that the transistors that have the same first number, such as transistors 3.4 and 3.3, are arranged to be mirrored along the reflection axis 60. Further, it is shown that typically the transistors with the same starting number are arranged along an axis that is vertical to each of the reflection axis 60, 62, 68, 70, so long as the transistors are not arranged directly on the reflection axis 60, 62, 68, 70. Further, the four transistor regions that each have a diagonal running reflection axis 60, 62, 68, 70, include a quadratic arrangement of the transistors contained therein. Between the four transistor regions and on an outer side of the transistor region empty regions are arranged, which are shown in FIG. 4 with the number “0”, whereby the empty regions that lie between the transistor regions are each arranged mirror symmetrical to one of the reflection axis 64. The reflection axis each run through the symmetry point 58. Accordingly, two of the transistor regions are arranged such that they each are mirrored to one of the reflection axis 64 or 66.

Through this highly symmetrical arrangement of the transistors 44, the differential amplifier also fulfills, also within each of the transistor areas, several symmetry requirements. In addition, the transistor regions are able to build upon one another by turning them 90 degrees about a vertical and through the symmetry point 58 running axis, and also through mirroring at one of the axis 64 or 65. Through such an embodiment, production based component dispersions are substantially reduced.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. Integrated amplifier circuit comprising an amplifier that is composed of at least two amplifier regions, the amplifier regions being arranged about a symmetry point, wherein each amplifier region has a plurality of transistors in a transistor region, and wherein transistors from different amplifier areas are arranged within the same transistor region.

2. The integrated amplifier circuit according to claim 1, wherein each transistor region has a symmetrical axis.

3. The integrated amplifier circuit according to claim 2, wherein at least a portion of the transistors are mirror imaged arranged along the symmetrical axis.

4. The integrated amplifier circuit according to claim 2, wherein the symmetrical axis is formed as a reflection action.

5. The integrated amplifier circuit according to claim 1, wherein the transistors in the transistor regions are arranged to be bilaterally symmetrical along the reflection axis.

6. The integrated amplifier circuit according to claim 1, wherein a reflection axis for the transistor regions pass through the symmetry point of the amplifier.

7. The integrated amplifier circuit according to claim 1, wherein the amplifier is wired as a differential amplifier.

8. The integrated amplifier circuit according to claim 1, wherein empty regions are located between the transistor regions.

9. The integrated amplifier circuit according to claim 1, wherein the transistors of the transistor region are arranged with four-way radial symmetry.
